(19) United States
(12) Patent Application Publication
(10) Pub. No.: US 2005/0006053 A1
(43) Pub. Date: Jan. 13, 2005

(54) Device and arrangement for fixing a profiled part to a bearing rail

(76) Inventors: Walter Apfelbacher, Freihung (DE); Norbert Reichenbach, Amberg (DE); Johann Seitz, Amberg (DE)

Correspondence Address: HARNESS, DICKEY & PIERCE, P.L.C., P.O.BOX 8910, RESTON, VA, 20195, US

(21) Appl. No.: 10/491,547

(22) PCT Filed: Sep. 25, 2002
(86) PCT No.: PCT/DE02/03616

(30) Foreign Application Priority Data
Oct. 2, 2001 (DE) 101 48 623.5

(51) Int. Cl. H05K 7/20

(52) U.S. Cl. 165/80.2

(57) ABSTRACT

The invention relates to a device (1) and an arrangement (2) for fixing a profiled part (4) to a bearing rail (5) which are simple and economical to manufacture. According to the invention, an adapter-type discrete connecting element (3) is used. Said connecting element comprises fixing means (6) which can be connected to the profiled part (4) and second (6) fixing means (7) which can be connected to the bearing rail (5).

This application is the national phase under 35 U.S.C. §371 of PCT International Application No. PCT/DE02/03616 which has an International filing date of Sep. 25, 2002, which designated the United States of America and which claims priority on German Patent Application number DE 101 48 623.5 filed Oct. 2, 2001, the entire contents of which are hereby incorporated herein by reference.

### FIELD OF THE INVENTION

The invention generally relates to a device and to an arrangement for fixing a profiled part or heat sink to a bearing rail.

### BACKGROUND OF THE INVENTION

DE 295 06 579 U1 discloses an arrangement which is intended for fixing electrical units to bearing rails and in the case of which the electrical units have a base with a latching-action fixing device subjected to spring pressure and by which it is possible for the electrical unit to be snap-fitted on the predetermined profile of the bearing rails and, if appropriate, released from the same again.

U.S. Pat. No. 5,598,322 A discloses a power control system which has a heat sink and can be installed on a DIN rail. The heat sink has integrally formed rail components which retain a mount assembly which can be pushed therein. The mount assembly comprises a mount and a movable slide, by means of which the heat sink can be fixed to a DIN rail.

DE 196 04 218 A1 discloses a heater with a profiled contact body, in the case of which fixing elements can be pushed into T-shaped grooves of a termination wall of the profiled contact body. The fixing elements serve for latching the heater on a standard top-hat rail.

### SUMMARY OF THE INVENTION

An object of an embodiment of the present invention is to specify a device and an arrangement which are intended for fixing a profiled part or heat sink to a bearing rail, and are constructed in a straightforward and cost-effective manner.

An object may be achieved according to an embodiment of the invention.

The device for fixing a profile part or a heat sink to a bearing rail serves, in particular, as a connecting element which is used on its own. It can thus be produced in a straightforward and cost-effective manner, and has associated, an adaptable fixing device which corresponds with longitudinal profiles of the bearing rail and/or of the heat sink and with the aid of which predetermined contours of the structural parts which are to be connected—heat sink and bearing rail—are rendered utilizable for fixing purposes without being changed in any way.

Provision is advantageously made for the first fixing device to be fitted on a first side of the connecting element and for the second fixing device to be fitted on a second side of the connecting element, the second side being located opposite the first. It is possible here for the connection to the bearing rail, on the one hand, and to the heat sink, on the other hand, to be produced in a particularly straightforward manner with just one connecting element arranged, as a joining part, between the heat sink and the bearing rail.

The fixing device(s) is/are advantageously designed as plug-in, push-in, snap-action or latching devices which correspond to structurally typical longitudinal profiles of the bearing rail and/or of the heat sink. Thus, despite profiles of the bearing rail and/or of the heat sink being acceptable without being changed in any way, there is a high degree of flexibility in respect of handling during connection of the structural parts—heat sink and bearing rail.

The first fixing device(s) is/are preferably designed in the manner of a clamp-like form-fitting surround of the heat sink, in particular of a cooling rib of the heat sink provided as the profiled part. This also makes it possible for profiled parts produced by extrusion—with contours and shaping provided exclusively in the extrusion direction—to be connected to the bearing rail without any need for adaptive change.

In a preferred configuration, at least one catch or at least one stop is arranged on the connecting element such that the heat sink, guided by the plug-in, push-in, snap-action or latching device(s), in the case of a movement in the longitudinal direction of the connecting element, can be fixed in its final installation position. It is possible here for a heat sink to be arrested, fixed in position or secured even when, on account of the position of the connecting element and the active gravitational force, it could otherwise be released automatically.

The connecting element is advantageously provided with a continuous surface in the direction of the bearing rail, as a result of which, on the one hand, insulation which is to be ensured is provided and, on the other hand, a directly electrically conductive connection can be avoided.

It is expedient for the fixing device(s) to be integrally formed on the connecting element, this being achieved, for example, by way of injection molding. An associated cut in the production device(s) required or a reduction in the number of structural components for multi-part fixing device(s) can thus likewise be realized.

The arrangement for fixing a heat sink to a bearing rail serves, in particular by virtue of the resulting spatial relationship of these to one another, as a straightforward and cost-effective connecting unit, with the aid of which given contours of the structural parts which are to be connected—heat sink and bearing rail—are rendered utilizable for fixing purposes without being changed in any way. The connecting element is advantageously fitted essentially transversely to structurally typical longitudinal profiles of the bearing rail and/or of the heat sink. It is thus possible for narrow heat sinks to be lined up in a row one beside the other in a space-saving manner and to be installed straightforwardly as joining parts.

In a preferred configuration, the heat sink, provided as the profiled part, is designed with cooling ribs running transversely to the connecting element, in particular for cooling an electrical component. The result is that it is easily possible to utilize a given shape of the heat sink for joining together with the connecting element.

It is advantageously possible for the heat sink and the electrical component to be combined to form an installation assembly. It is possible for a dedicated fixing device for the electrical unit to be dispensed with and for unit-generated heat to be advantageously dissipated via the heat sink.

Further advantages, features and details of the invention will become evident from the description of illustrated exemplary embodiments given hereinbelow and the accompanying drawings, which are given by way of illustration only and thus are not limitative of the present invention, wherein:

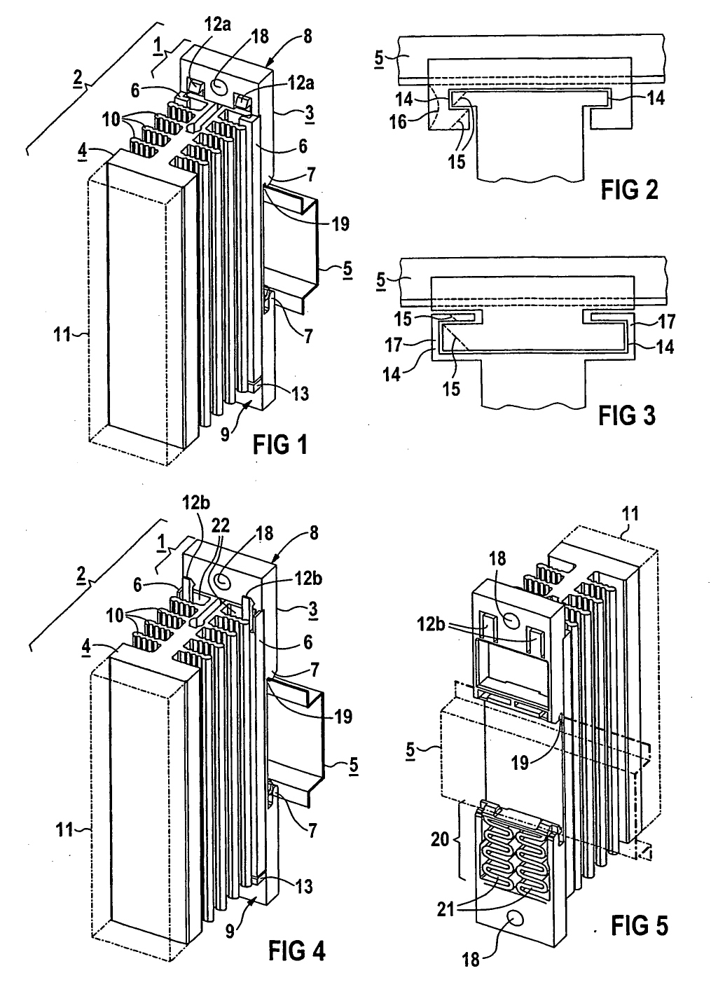

FIG. 1 shows a first three-dimensional illustration of a device and an arrangement for fixing a heat sink to a bearing rail by use of a connecting element and a catch,

FIG. 2 shows, schematically, a device and an arrangement according to FIG. 1 in a plan view,

FIG. 3 shows a second three-dimensional illustration of a device and an arrangement according to FIG. 1, and

FIG. 4 shows a three-dimensional illustration of a device and an arrangement according to FIG. 1 with a further configuration of the catch.

In the following text, the same parts are provided with the same designations in the figures.

### DETAILED DESCRIPTION OF THE PREFERRED EMBODIMENTS

FIG. 1 shows a device 1 and an arrangement 2 with a discrete adapter-like connecting element 3 for fixing a heat sink 4 to a bearing rail 5. The connecting element 3 has first fixing device 6, which are connected to the heat sink 4, and second fixing device 7, which are connected to the bearing rail 5. The first fixing device 6 are fitted on a first side 8 of the connecting element 3 and the second fixing device 7 are fitted on a second side 9 of the connecting element 3, the second side being located opposite the first. The connecting element 3 here is fitted essentially transversely to structurally typical longitudinal profiles of the bearing rail 5 and/or of the heat sink 4.

In addition, the fixing devices 6, 7 are integrally formed on the connecting element 3. Accordingly, it is possible to produce both a connection to the heat sink 4 and the connection to the bearing rail 5 using just one connecting element, in particular made of plastic. It is advantageously the case here that there is no need for any particular assembly or fixing techniques, this resulting in a high degree of automation and, consequently, in an advantageous connecting element. The connecting element 3 and its fixing devices 6, 7 are generally adapted to the shapes and contours of the structural parts which are to be fixed—heat sink 4 and bearing rail 5. The resulting complex fixing devices 6, 7 in the form of plug-in, push-in, snap-action or latching device can easily be produced as a plastic molding, in particular as a plastic injection molding, which, in the case of the heat sink 4.

Furthermore, the connecting element 3—alternatively also one of the fixing devices 6, 7—has at least first catches 12a and/or one or more stops 13. The first catches 12a are integrated resiliently in the connecting element 3 on the introduction side and, by virtue of their beveled ends, make it possible for the heat sink 4 to be attached thereto. If appropriate, it is also possible to use just one of the first catches 12a. The stop 13 is fitted in a fixed or removable manner at the end of the connecting element 3. The first catches 12a and/or the stop 13 are/is designed and positioned such that the heat sink 4, guided by the plug-in, push-in, snap-action or latching device, in the case of a movement in the longitudinal direction of the connecting element 3, can be fixed in its final installation position. This effectively prevents the heat sink 4 from sliding out.

The heat sink 4 is designed with cooling ribs 10 running transversely to the connecting element 3, for cooling an electrical component 11. It is possible here, on the heat sinks, which are usually produced by extrusion, for contours and shapes provided in the extrusion direction advantageously to be utilized for fixing purposes without any modifications. If appropriate, one of the cooling ribs 10 may be adapted in its dimensions to the connecting element 3, if appropriate reduced in its extruded width in relation to the respective overall width of the connecting element 3.

Furthermore, in an advantageous configuration, the heat sink and the electrical unit 11 are combined to form an installation assembly. The combining operation may be carried out by plug-in action, push-in action or in an equivalent manner. The connecting element 3 may be designed with different overall widths, in particular with the overall widths 17.5 mm, 22.5 mm and 45 mm, and preferably with an overall width which corresponds to ≦ the overall width of the electrical component 11.

The electrical component 11 may be an electronic contactor, a semiconductor relay, an ohmic load, a series installation unit, a power electronics unit or a similar component or unit. The resulting advantage is that, for the purpose of fixing a unit and/or a heat sink to a bearing rail, it is possible to avoid additional parts made of metal and/or plastic which may be necessary and, consequently, also associated joining operations, for example screw connection or caulking. Correlating operations and production costs are thus reduced.

The bearing rail 5 serves as a joining element for fixing the connecting element 3 coupled thereto, for example, to an installation panel of a switch cabinet, it being possible to use different bearing-rail profiles.

FIG. 2 shows, schematically, the device 1 and the arrangement according to FIG. 1 in a plan view. The device 1 and the arrangement 2 here connect, on the one hand, the bearing rail 5 and, on the other hand, the heat sink 4 to one another and/or produce the spatial relationship of these to one another. The first fixing device 6, which belong to the connecting element 3, are designed here as plug-in, push-in, snap-action or latching means which corresponds to structurally typical longitudinal profiles of the bearing rail 5 and/or of the heat sink 4.

Furthermore, the first fixing device(s) 6 is/are designed with lateral guides 14 in the manner of a clamp-like form-fitting surround of the heat sink 4, in particular of a cooling rib 10. At least one bevel 15 which may be provided and/or a wall reduction 16 have/has as a favorable effect on the connecting operation between the heat sink 4 and the connecting element 3, this making possible, or facilitating, a snap-action or latching operation as an alternative to a plug-in or push-in operation.

FIG. 3 shows a second three-dimensional illustration of the device 1 and the arrangement 2 according to FIG. 1. The connecting element 3 here has at least one fixing opening 18 which, by use of conventional screws, rivets or the like, can serve as an alternative to the second fixing device(s) 7 in conjunction with the bearing rail 5. The second fixing device(s) 7, for their part, have, at a first location, a groove 19 which can accommodate and guide the bearing rail 5 on one side.

Furthermore, at a second location, which is located opposite the first location, the second fixing device(s) 7 is/are provided integrally with a latching mechanism 20 with a spring 21 integrally molded on the connecting element 3, this allowing snap-fitting on the bearing rail 5. Accordingly, the second fixing device(s) 7 may serve as plug-in, push-in, snap-action or latching means and fix the connecting element 3 and/or the heat sink 4 and/or the electrical unit 11 to the bearing rail 5.

The connecting element 3 has a continuous surface in the direction of the bearing rail 5, with the result that a conductive connection or partial insulation is avoided.

FIGS. 3 and 4 show a three-dimensional illustration of the device 1 and the arrangement 2 according to FIG. 1 in each case with a further configuration of the first catches 12a in the form of second catches 12b, in which case the second catches 12b engage through a corresponding cutout 22 in a cooling rib 10 of the heat sink 4 and fix the latter in its final installation position.

Exemplary embodiments being thus described, it will be obvious that the same may be varied in many ways. Such variations are not to be regarded as a departure from the spirit and scope of the present invention, and all such modifications as would be obvious to one skilled in the art are intended to be included within the scope of the following claims.

1. A device for fixing a profiled part, including cooling ribs, to a bearing rail, comprising:
a connecting element including a first fixing device, connectable to the profiled part and a second fixing device, connectable to the bearing rail, wherein
the fixing devices respectively correspond to structurally typical longitudinal profiles of the bearing rail and to one of the cooling ribs.

2. The device as claimed in claim 1, wherein
the first fixing device is fitted on a first side of the connecting element and the second fixing device is fitted on a second side of the connecting element, the second side being opposite the first side.

3. The device as claimed in claim 1, wherein
the fixing devices are designed as least one of plug-in, push-in, snap-action and latching.

4. The device as claimed in claim 1, wherein
the first fixing device is designed to be clamp-like and form-fitting, surrounding the cooling rib.

5. The device as claimed in claim 3, further comprising:
at least one of at least one catch and at least one stop, arranged on the connecting element such that the profiled part, guided by at least one of the plug-in, push-in, snap-action and latching, in the case of a movement in the longitudinal direction of the connecting element is fixable in its final installation position.

6. The device as claimed in claim 1,
wherein the connecting element is designed with a continuous surface in the direction of the bearing rail.

7. The device as claimed in claim 1, wherein
the fixing devices are integrally formed on the connecting element.

8. The device as claimed in claim 1, wherein
the connecting element is designed as a plastic molding.

9. An arrangement comprising:
a connecting element, including first and second fixing devices;
a profiled part including cooling ribs, connected to the first fixing device; and
a bearing rail, connected to the second fixing device, wherein
the fixing devices respectively correspond to a structurally typical longitudinal profile of the bearing rail and to one of the cooling ribs.

10. The arrangement as claimed in claim 9, wherein
the connecting element is fitted essentially transversely to structurally typical longitudinal profiles of at least one of the bearing rail and the profiled part.

11. The arrangement as claimed in claim 9, wherein the profiled part designed with cooling ribs runs transversely to the connecting element.

12. The arrangement as claimed in claim 11, wherein
the profiled part and an electrical component are combined to form an installation assembly.

13. A device as claimed in claim 1, wherein the profiled part is a heat sink, including cooling ribs.

14. A device as claimed in claim 1, wherein the connecter element is discrete and adapter-like.

15. The device as claimed in claim 2, wherein the fixing devices are designed as at least one of plug-in, push-in, snap-action and latching.

16. The device as claimed in claim 1, wherein the first fixing device is designed to be clamp-like and form-fitting, surrounding the cooling rib.

17. The device as claimed in claim 2, wherein the connecting element is designed with a continuous surface in the direction of the bearing rail.

18. The device as claimed in claim 2, wherein the fixing devices are integrally formed on the connecting element.

19. The device as claimed in claim 1, wherein the connecting element is designed as an injection plastic molding.

20. The arrangement as claimed in claim 10, wherein the profiled part designed with cooling ribs runs transversely to the connecting element.

21. The arrangement as claimed in claim 9, wherein the profiled part designed with cooling ribs runs transversely to the connecting element, for cooling an electrical component.

22. The arrangement as claimed in claim 21, wherein the profiled part and the electrical component are combined to form an installation assembly.

23. The arrangement as claimed in claim 9, wherein the profiled part is a heat sink, including cooling ribs.

24. The arrangement as claimed in claim 9, wherein the connecter element is discrete and adapter-like.
